(19) United States
(12) Patent Application Publication
(10) Pub. No.: US 2023/0174861 A1
(43) Pub. Date: Jun. 8, 2023

(54) NARROWBAND QUANTUM DOTS AND METHODS OF MAKING THEM

(71) Applicant: Applied Materials, Inc., Santa Clara, CA (US)

(72) Inventors: Sivapackia Ganapathiappan, Los Altos, CA (US); Nag Patibandla, Dublin, CA (US); Gopi Chandran Ramachandran, Mumbai (IN); Srinivas Oruganti, Hyderabad (IN); Saikat Sen, Kolkata (IN); Mahesh Kumar Uppada, Hyderabad (IN); Arunangshu Biswas, Nadia (IN)

(73) Assignee: Applied Materials, Inc., Santa Clara, CA (US)

(21) Appl. No.: 18/070,703

(22) Filed: Nov. 29, 2022

Related U.S. Application Data
(60) Provisional application No. 63/285,573, filed on Dec. 3, 2021.

(51) Int. Cl. C09K 11/88

(52) U.S. Cl. CPC C09K 11/883; B82Y 20/00

(57) ABSTRACT

Methods of making a multilayered semiconductor particle, which may be referred to as a quantum dot, are described. The methods include combining a first zinc-containing compound and a selenium-containing compound to form a ZnSe mixture. The zinc-containing compound and the selenium-containing compound are rapidly combined in less than or about 5 seconds. The methods also include adding a tellurium-containing compound to the ZnSe mixture to form at least one ZnSeTe particle in a ZnSeTe mixture. The methods still further include forming a first shell layer on the ZnSeTe particle and forming a second shell layer on the first shell layer to make the multilayered semiconductor particle. In additional embodiments, the reactant and particle mixtures may be rapidly stirred. The light emitted by the multilayered semiconductor particles may be characterized by an enhanced narrowband emission profile (i.e., sharpness).

### CROSS-REFERENCE TO RELATED APPLICATIONS

This application claims the benefit of, and priority to U.S. Provisional Application Serial No. 63/285,573, filed Dec. 3, 2021, which is hereby incorporated by reference in its entirety for all purposes.

### TECHNICAL FIELD

The present technology relates to narrowband-emitting quantum dots and methods of making them. More specifically, the present technology relates to quantum dots made of multiple layers of inorganic materials.

### BACKGROUND

High-resolution light-emitting diode (LED) displays can include millions of micron-sized pixels arranged to form a viewing screen. Conventional LED displays generate a color image by filtering down white light from an LED light source into red, green, and blue pixels that emit at varying intensities across the viewing screen. Other LED displays excite organic or inorganic compounds so they emit light of a particular color, such as red, green, or blue light, depending on the pixel. These LED displays typically require fewer filters to block the light of unwanted colors, which can improve their brightness and power efficiency. However, there are many challenges with making light-emitting materials, including challenges with making materials that emit a sharp, consistent color across batches, as well as challenges with making materials that are stable over the lifetime of the display.

Thus, there is a need for high-quality materials for LED display devices. These and other needs are addressed by the present technology.

### SUMMARY

Embodiments of the present technology include methods of making a multilayered semiconductor particle that may be referred to as a quantum dot. The methods include combining a first zinc-containing compound and a selenium-containing compound to form a ZnSe mixture. The zinc-containing compound and the selenium-containing compound are rapidly combined in less than or about 5 seconds. The methods also include adding a tellurium-containing compound to the ZnSe mixture to form at least one ZnSeTe particle in a ZnSeTe mixture. The methods still further include forming a first shell layer on the ZnSeTe particle and forming a second shell layer on the first shell layer to make the multilayered semiconductor particle.

In additional embodiments, the tellurium-containing compound is added to the ZnSe mixture in less than or about 5 seconds. In further embodiments, the method also includes increasing a temperature of the ZnSeTe mixture at a rate greater than or about 10° C./minute. In still further embodiments, the method also includes stirring the ZnSeTe mixture with a stirring mechanism rotating at greater than or about 1500 RPM. In yet additional embodiments, the tellurium-containing compound is added to the ZnSe mixture in an atmosphere that includes less than or about 1 mol.% oxygen. In more embodiments, the ZnSeTe mixture includes less than or about 1 wt.% water. In still additional embodiments, the first shell layer includes zinc selenide (ZnSe). In yet more embodiments, the second shell layer includes zinc sulfide (ZnS).

Embodiments of the present technology include more methods of making a multilayered semiconductor particle. The methods include combining a first zinc-containing compound and a selenium-containing compound to form a ZnSe mixture. The methods also include adding a tellurium-containing compound to the ZnSe mixture to form at least one ZnSeTe particle in a particle forming mixture. The particle forming mixture is stirred with a stirring mechanism rotating at greater than or about 1500 RPM during the formation of the at least one ZnSeTe particle. The methods further include forming a ZnSe-containing shell layer on the ZnSeTe particle, and forming a ZnS-containing shell layer on the ZnSe-containing shell layer to make the multilayered semiconductor particle.

In additional embodiments, the particle forming mixture is stirred with the stirring mechanism rotating at greater than or about 1500 RPM during the formation of the ZnSe-containing shell layer and the ZnS-containing shell layer. In yet additional embodiments, the zinc-containing compound and the selenium-containing compound are combined in less than or about 5 seconds. In further embodiments, the tellurium-containing compound is added to the ZnSe mixture in less than or about 5 seconds. In still further embodiments, the particle forming mixture is characterized by a temperature of greater than or about 300° C. during the formation of the at least one ZnSeTe particle. In more embodiments, the particle forming mixture includes an alkyl phosphine compound.

Embodiments of the present technology further include a multilayered semiconductor particle. The particle includes a core that includes ZnSeTe, and an inner shell layer that includes ZnSe in contact with the core. The particle also includes an outer shell layer that includes ZnS in contact with the inner shell layer. The multilayered semiconductor particle has a light emission spectrum characterized by a primary peak with a full-width-half-maximum wavelength range of less than or about 40 nm.

In additional embodiments, the primary peak of the light emission spectrum of the particle is less than or about 455 nm. In further embodiments, an emission intensity of the primary peak of the light emission spectrum exceeds an emission intensity of every other emission peak in the light emission spectrum by a ratio greater than or about 10:1. In still further embodiments, the multilayered semiconductor particles is characterized by an average particle size of less than or about 10 nm. In yet additional embodiments, the core is sulfur-free. In more embodiments, the multilayered semiconductor particle is incorporated into a microLED device.

Embodiments of the present technology provide improved quantum dot particles that are characterized by a narrowband emission of light. In embodiments, the present quantum dot particles may be characterized by an emissions peak having a full-width-half-maximum (FWHM) size spanning less than or about 40 nm. In some embodiments, the emissions peak may be characterized by a FWHM of less than or about 10 nm. In further embodiments, the primary, narrowband emissions peak may be significantly more intense than any other emission peak from the quantum dot particles. In embodiments, an intensity ratio of the primary emissions peak to the next most intense emissions peak may be greater than or about 10:1. These characteristics of the present quantum dot particles permit them to emit light that is very sharp and monochromatic. They can find applications in displays such as microLED displays that want to reproduce sharp colors without needing one or more layers of color filters that can significantly reduce the brightness of the display. These and other embodiments, along with many of their advantages and features, are described in more detail in conjunction with the below description and attached figures.

### BRIEF DESCRIPTION OF THE DRAWINGS

A further understanding of the nature and advantages of the disclosed embodiments may be realized by reference to the remaining portions of the specification and the drawings.

FIG. 1 shows a flowchart with selected operations in a method of making a multilayered semiconductor particle according to embodiments of the present technology.

FIG. 2 shows another flowchart with selected operations in a method of making a multilayered semiconductor particle according to embodiments of the present technology.

FIG. 3 shows a simplified cross-sectional drawing of a multilayered semiconductor particle according to embodiments of the present technology.

FIG. 4 shows a simplified cross-sectional schematic drawing of a display device incorporating the multilayered semiconductor particles according to embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the figures, similar components and/or features may have the same numerical reference label. Further, various components of the same type may be distinguished by following the reference label by a letter that distinguishes among the similar components and/or features. If only the first numerical reference label is used in the specification, the description is applicable to any one of the similar components and/or features having the same first numerical reference label irrespective of the letter suffix.

### DETAILED DESCRIPTION

Quantum dots are nanometer-sized particles of inorganic materials that can emit light of a particular color after being excited by more energetic light. The color of the emitted light may depend on one or more characteristics of the particles, including their size, shape, and composition, among other characteristics. For quantum dots made of inorganic semiconductor materials, the color of the light they emit depends on an energy gap between the conduction band and the valence band of the dots. When the quantum dots are excited, one or more electrons jump from the lower-energy conduction band to the higher-energy valence band. As the excited electrons fall back down to the conduction band, they emit light having a color that depends on the size of the energy gap between the valence band and the conduction band. The narrower the energy gap, the more the emitted light is shifted to the red, while the wider the energy gap, the more the emitted light is shifted to the blue. By adjusting one or more characteristics of the quantum dots that change the energy gap between the conduction and valence bands, quantum dots can be made that emit light of practically any color in the visible spectrum.

The efficiency of quantum dots in converting high-energy white or ultraviolet light into specific colors of visible light has made them increasingly popular to use in electronic displays such as light-emitting-diode (LED) displays. The ability of the quantum dots to emit one color of light reduces the number of color filters and polarizers needed in a display to block unwanted colors of light from contaminating the displayed images. In many cases, the quantum-dot-containing displays are brighter, higher-contrast, and more energy-efficient than conventional LED displays that lack quantum dots.

The inorganic semiconductor materials used to make many types of quantum dots are also more stable than other kinds of color-specific photoluminescent compounds, such as many of the organic compounds used in organic-light-emitting-diode (OLED) displays. The inorganic quantum dots can undergo many excitation-emission cycles before chemical changes in the semiconductor materials significantly reduce their conversion efficiency. In contrast, the complex organic molecules used in OLED displays are more prone to chemical breakdown over time. The organic molecules are also more sensitive than inorganic quantum dots to water and other contaminants quenching their photoluminescence.

Unfortunately, there are still many challenges with efficiently fabricating quantum dots that are characterized by a sharp color profile centered on a precise emission wavelength. In many cases, the quantum dots are formed with a lot of variability in the size, shape, and composition of the dots, among other variables. Quantum dots that include multiple layers of materials starting with an inner core and one or more surrounding shells can experience further variability in the relative sizes and compositions of the core and shell components. The variability can result in a batch of quantum dots with a broad color profile characterized by wide wavelength emission peaks with a full-width-half-maximums (FWHMs) of 50 nm or more. The variability can also lead to alternate quantum-dot-formation pathways that produce significant secondary light emission peaks in the quantum dot material. In some cases, the ratio of light emission intensity between a significant secondary emission peak and the primary emission peak may be greater than or about 0.1:1, greater than or about 0.2:1, greater than or about 0.5:1, or more. In some instances, a secondary peak may be expressed as a shoulder on the primary emission peak, while in other instances, the secondary peak may be a distinct peak in the light emission spectrum of the quantum dot material.

A wide emission peak around the primary emission wavelength and one or more significant secondary emission peaks can substantially reduce the sharpness of the color emitted by the quantum dot material. Light emissions characterized by a sharper color have a narrower FWHM spectral peak profile than light emissions that have less color sharpness. This reduced color sharpness can result in displayed images characterized by duller-looking colors, reduced color contrast, and unwanted hues, among other color defects. In many instances, the reduction in color sharpness may be correlated with shorter wavelength (i.e., bluer color) emission peaks. In these instances, a quantum dot material made for a 550 nm light emission peak (i.e., green light) may have a sharper color profile than a similar quantum dot material made for a 450 nm light emission peak (i.e., blue light).

The present technology addresses the challenges with variability in the emissions characteristics of inorganic quantum dot materials by using one or more techniques in the fabrication of the quantum dots that reduce this variability and increase the color sharpness of the emitted light. Embodiments of the present technology include methods of making multilayered semiconductor quantum dot particles that include the rapid combining of at least some of the reactants to make the core of the particles. It has been discovered that the rapid combination of these reactants produces more uniform particle cores that contribute to a reduced light emission variability and increased color sharpness of the light emitted from the quantum dot material. In further embodiments, reactants to make the shell layer in contact with the core may also be rapidly combined. Additional embodiments of the present technology include the rapid stirring of the mixture at one or more operations in the formation of the multilayered quantum dots. It has been discovered that the rapid stirring of the mixture in which the particle cores are formed produces more uniform particle cores that can also contribute to a reduced light emission variability and increased color sharpness of the light emitted from the quantum dot material. In further embodiments, the particle mixture may be rapidly stirred during operations to make the shell layer in contact with the core. In yet more embodiments, the particle mixture may be rapidly stirred during the formation of an additional layer on the first shell layer in contact with the core.

The present technology is able to produce inorganic quantum dots that are characterized by an increased color sharpness and fewer and less intense secondary light emission peaks compared to conventional fabrication methods. In embodiments, the quantum dots may include a multilayered structure of semiconductor materials that include a particle core made from a first group of semiconductor materials, an inner shell made from a second group of semiconductor materials, and an outer shell made from a third group of materials. In additional embodiments, the present technology may include quantum dots characterized by a peak light emission wavelength of less than or about 455 nm and a full-width-half-maximum wavelength range of less than or about 40 nm. These quantum dots may be referred to as having a sharp blue light emission profile.

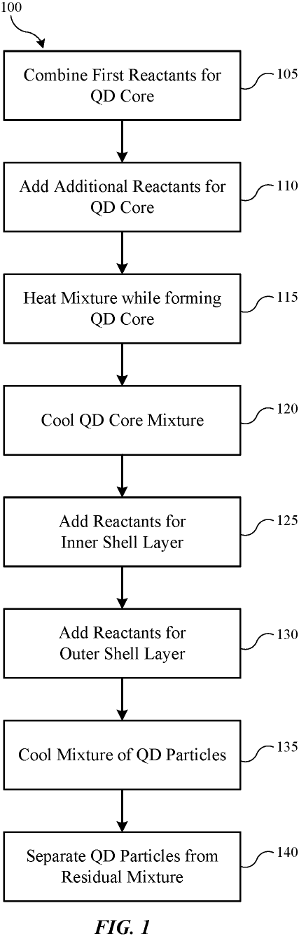

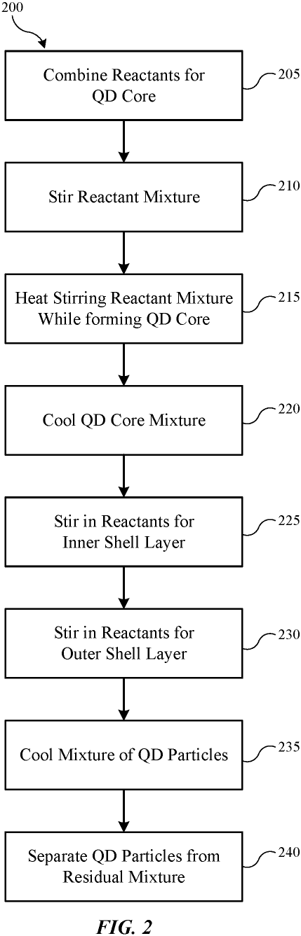

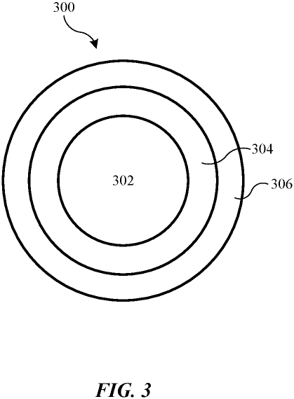

FIG. 1 and FIG. 2 show flowcharts illustrating some of the operations in embodiments of the present methods to make a multilayered semiconductor particle. FIG. 3 shows a simplified cross-sectional drawing of an embodiment of one of those multilayered semiconductor particles made by the present technology. Method 100 shown in FIG. 1 and method 200 shown in FIG. 2 may or may not include operations prior to the initiation of the methods, including the preparation of the reactants that are combined to make the core and shells of the multilayered semiconductor particles. Methods 100 and 200 may also include a number of optional operations, which may or may not be specifically associated with some embodiments of methods according to the present technology.

Referring specifically to FIG. 1, method 100 includes combining first reactants incorporated into the core of the multilayered semiconductor particle (i.e., the quantum dot) at operation 105. In embodiments, these first reactants are rapidly combined in a short period of time. In further embodiments, the combination time may be less than or about 10 seconds, less than or about 7.5 seconds, less than or about 5 seconds, less than or about 2.5 seconds, less than or about 1 second, or less. The rapid combination of the reactants reduces localized concentration centers of one of the reactants that can lead to a less uniform formation of the quantum dot cores, such as QD core 302 of the multilayered semiconductor particle 300 shown in FIG. 3.

In embodiments, the first reactants that are combined in operation 105 may include two or more semiconductor-containing reactants. In further embodiments, the first reactants may include at least one zinc-containing compound and at least one selenium-containing compound, among other first reactants. In more embodiments, the at least one zinc-containing compound may be an organo-zinc compound, among other zinc-containing compounds. In yet more embodiments, the organo-zinc compound may be zinc acetate or zinc stearate, among other organo-zinc compounds. In still further embodiments, the organo-zinc compound may be anhydrous, such as anhydrous zinc acetate. In embodiments, the at least one selenium compound may be selenium complexed with an organo-phosphorous complexing agent. In additional embodiments, the organo-phosphorous complexing agent may be a trialkyl-phosphine compound. In further embodiments, the trialkyl-phosphine compound may be one or more of trihexylphosphine, triseptylphosphine, triocetylphosphine, and trinonylphosphine, among other trialkyl phosphine compounds.

In further embodiments, the first reactants may further include additional compounds that facilitate the rapid combination of the at least one zinc-containing compound and the at least one selenium-containing compound. In embodiments, these additional compounds may include unsaturated or saturated alkyl hydrocarbons having greater than or about 10 carbon atoms, greater than or about 12 carbon atoms, greater than or about 15 carbon atoms, greater than or about 18 carbon atoms, greater than or about 20 carbon atoms or more. In more embodiments, the alkyl hydrocarbons may include one or more of 1-octadecene, 1-decene, 1-hexadecene, 1-dodecene, 1-eicosene, and tetradecene, among other alkyl hydrocarbons. In further embodiments, these additional compounds may include organic acids having greater than or about 12 carbon atoms, greater than or about 15 carbon atoms, greater than or about 18 carbon atoms, greater than or about 20 carbon atoms or more. In more embodiments, the organic acids may include one or more of acetic acid, propionic acid, butyric acid, valeric acid, caproic acid, heptanoic acid, caprylic acid, capric acid, undecanoic acid, lauric acid, myristic acid, palmitic acid, stearic acid, behenic acid, acrylic acid, methacrylic acid, but-2-enoic acid, but-3-enoic acid, pent-2-enoic acid, pent-4-enoic acid, hex-2-enoic acid, hex-3-enoic acid, hex-4-enoic acid, hex-5-enoic acid, hept-6-enoic acid, oct-2-enoic acid, dec-2-enoic acid, undec-10-enoic acid, dodec-5-enoic acid, oleic acid, gadoleic acid, erucic acid, linoleic acid, α-linolenic acid, calendic acid, eicosadienoic acid, eicosatrienoic acid, arachidonic acid, stearidonic acid, benzoic acid, para-toluic acid, ortho-toluic acid, meta-toluic acid, hydrocinnamic acid, and oleic acid, among other organic acids.

In additional embodiments, the first reactants may be combined at a temperature of greater than or about 90° C., greater than or about 100° C., greater than or about 110° C., greater than or about 120° C., greater than or about 130° C., greater than or about 140° C., greater than or about 150° C., or more. In more embodiments, the temperature of the combined first reactants may be increased to greater than or about 160° C., greater than or about 170° C., greater than or about 180° C., greater than or about 190° C., greater than or about 200° C., greater than or about 210° C., greater than or about 220° C., or more while the combined first reactants react to form a first portion of the QD cores. In further embodiments, the first portion of the QD cores may include zinc and selenium. In still further embodiments, the first portion of the QD cores may be tellurium-free.

Method 100 may further include adding additional reactants to the first portion of the QD cores at operation 110. In embodiments, these additional reactants may be rapidly added to the mixture that includes the first portion of the QD cores in a short period of time. In further embodiments, the addition time may be less than or about 10 seconds, less than or about 7.5 seconds, less than or about 5 seconds, less than or about 2.5 seconds, less than or about 1 second, or less. The rapid addition of the additional reactants reduces localized concentration centers of one of the reactants that can lead to less uniform incorporation of the additional reactants into the first portion of the quantum dot cores. In additional embodiments, the additional reactants may include one or more tellurium-containing reactants. In yet additional embodiments, the tellurium-containing reactants may include tellurium complexed with an organo-phosphorous complexing agent. In additional embodiments, the organo-phosphorous complexing agent may be a trialkyl-phosphine compound. In further embodiments, the trialkyl-phosphine compound may be one or more of trihexylphosphine, triseptylphosphine, triocetylphosphine, and trinonylphosphine, among other trialkyl phosphine compounds. In embodiments, the addition of the additional reactants to the first portion of the QD cores may create a mixture of the QD core reactants.

Method 100 may also include heating the mixture of the QD core reactants at operation 115. In embodiments, the mixture may be heated to a temperature greater than or about 250° C., greater than or about 260° C., greater than or about 270° C., greater than or about 280° C., greater than or about 290° C., greater than or about 300° C., or more. In further embodiments, the increase in temperature may be characterized by a temperature ramp-up rate of greater than or about 10° C./minute, greater than or about 11° C./minute, greater than or about 12° C./minute, greater than or about 13° C./minute, greater than or about 14° C./minute, greater than or about 15° C./minute, or more. The elevated temperature of the mixture provides efficient incorporation of the additional reactants into the first portion of the QD cores to form a full QD core, such as QD core 302. In embodiments, the QD core 302 may include zinc, selenium, and tellurium in a ZnSeTe core. In further embodiments, the mixture of the QD core reactants may remain at the heated temperature for greater than or about 30 minutes, greater than or about 45 minutes, greater than or about 60 minutes, greater than or about 75 minutes, greater than or about 90 minutes, greater than or about 100 minutes, greater than or about 120 minutes, or more, while the QD core 302 is being formed.

Method 100 may still further include cooling the heated mixture of the QD core 302 particles at operation 120. The cooling operation may lower the temperature of the heated mixture to less than or about 290° C., less than or about 280° C., less than or about 270° C., less than or about 260° C., less than or about 250° C., or less. In additional embodiments, the decrease in temperature may be characterized by a temperature ramp-down rate of less than or about 10° C./minute, less than or about 7.5° C./minute, less than or about 5° C./minute, less than or about 2.5° C./minute, less than or about 1° C./minute, or less. In embodiments, the cooling operation reduces the temperature of the heated mixture of the QD core 302 particles in preparation for the addition of the inner shell reactants to the QD core particles. The reduced temperature permits the inner shell reactants to distribute more evenly through the QD core 302 particles before they react and form the inner shell layer 304 around the QD core 302.

Method 100 may also further include adding the inner shell layer reactants to the reduced-temperature mixture of QD core particles at operation 125. In embodiments, the inner shell reactants may be rapidly added to the mixture of QD core particles in a short period of time. In further embodiments, the addition time may be less than or about 10 seconds, less than or about 7.5 seconds, less than or about 5 seconds, less than or about 2.5 seconds, less than or about 1 second, or less. The rapid addition of the inner shell reactants reduces concentration centers of the reactants that can lead to wider variations in the characteristics of the inner shells, such as inner shell 304 surrounding QD core 302 in the multilayered semiconductor particle 300. These inner shell characteristics may include the composition and thickness of the inner shell 304, among other characteristics. In embodiments, the inner shell 304 may have a thickness of greater than or about 0.5 nm, greater than or about 1 nm, greater than or about 1.5 nm, greater than or about 2 nm, greater than or about 2.5 nm, greater than or about 3 nm, greater than or about 3.5 nm, greater than or about 4 nm, greater than or about 4.5 nm, greater than or about 5 nm, greater than or about 5.5 nm, greater than or about 6 nm, or more.

In embodiments, the inner shell reactants may include a zinc-containing reactant and a selenium-containing reactant, among other reactants. In additional embodiments, the zinc-containing reactant may include anhydrous zinc acetate, and the selenium-containing reactant may include selenium combined with a complexing agent such as triocetylphosphine. In further embodiments, the inner shell reactants may include additional compounds such as unsaturated or saturated alkyl hydrocarbons and organic acids. In still further embodiments, the unsaturated or saturated alkyl hydrocarbons may include 1-octadecene, and the organic acids may include oleic acid. In more embodiments, the inner shell 304 formed from the inner shell reactants may include a zinc-selenium (ZnSe) material. In additional embodiments, the combined mixture of the inner shell reactants and the QD core particles may be heated to facilitate the formation of the inner shell 304 on the QD core 302. In more embodiments, the combined mixture may be heated to a temperature of greater than or about 250° C., greater than or about 260° C., greater than or about 270° C., greater than or about 280° C., greater than or about 290° C., greater than or about 300° C., or more. In yet more embodiments, the combined mixture may be heated to the heated temperature for greater than or about 1 minute, greater than or about 2.5 minutes, greater than or about 5 minutes, greater than or about 7.5 minutes, greater than or about 10 minutes, or more.

Method 100 may still also include adding the outer shell layer reactants to the particle mixture at operation 130. In embodiments, the outer shell mixture may be rapidly added to the mixture of particles in a short period of time. In further embodiments, the addition time may be less than or about 10 seconds, less than or about 7.5 seconds, less than or about 5 seconds, less than or about 2.5 seconds, less than or about 1 second, or less. The rapid addition of the outer shell reactants reduces concentration centers of the reactants that can lead to wider variations in the characteristics of the outer shells, such as outer shell 306 surrounding inner shell 304 in the multilayered semiconductor particle 300. These outer shell characteristics may include the composition and thickness of the outer shell 306, among other characteristics. In embodiments, the outer shell 306 may have a thickness of greater than or about 1 nm, greater than or about 2 nm, greater than or about 3 nm, greater than or about 4 nm, greater than or about 5 nm, or more.

In additional embodiments, the combined mixture of the outer shell reactants and the particles may be maintained at the same heated temperature of the combined mixture of the inner shell reactants and the QD cores 302. The temperature of the combined mixture of the outer shell reactants and the particles may be greater than or about 250° C., greater than or about 260° C., greater than or about 270° C., greater than or about 280° C., greater than or about 290° C., greater than or about 300° C., or more. In yet more embodiments, the combined mixture may be held at the heated temperature for greater than or about 1 minute, greater than or about 2.5 minutes, greater than or about 5 minutes, greater than or about 7.5 minutes, greater than or about 10 minutes, or more, to facilitate the formation of the outer shell 306 on inner shell 304 of the multilayered semiconductor particle 300.

In further embodiments, the outer shell reactants may include a zinc-containing reactant and a sulfur-containing reactant, among other reactants. In additional embodiments, the zinc-containing reactant may include anhydrous zinc acetate, and the sulfur-containing reactant may include sulfur combined with a complexing agent such as triocetylphosphine. In yet additional embodiments, the sulfur-containing reactant may include one or more of 1-octanethiol, 1-dodecanethiol, 1-octadecanethiol, tributylphosphine sulphide, cyclohexyl isothiocyanate, α-toluenethiol, ethylene trithiocarbonate, allyl mercaptan, bis(trimethylsilyl) sulphide, trioctylphosphine sulphide, 1-undecanethiol, 1-hexadecanethiol, 1-tetradecanethiol, 1-decanethiol, 2-phenylethanethiol, 4-methylbenzenethiol, 4-methoxybenzyl mercaptan, tert-dodecylmercaptan, 2-,3-,10-mercaptopinane, cyclohexanethiol, and di-tert-butyl disulfide, among other sulfur-containing reactants. In still more embodiments, the sulfur-containing reactant may include one or more of a poly(ethylene glycol) methyl ether thiol of molecular weight 600 to 3000, a poly(ethylene glycol) dithiol of molecular weight 600 to 3000, a alkanedithiol of formula HSCH₂(CH₂)ₙCH₂SH (n=2-30), trimethylolpropane tris(3-mercaptopropionate, 2,2′-(ethylenedioxy)diethanethiol, among other sulfur-containing reactants.

In further embodiments, the outer shell reactants may include additional compounds such as unsaturated or saturated alkyl hydrocarbons and organic acids. In still further embodiments, the unsaturated or saturated alkyl hydrocarbons may include 1-octadecene, and the organic acids may include oleic acid. In more embodiments, the outer shell 306 formed from the outer shell reactants may include a zinc sulfide (ZnS) material. The outer shell 306 provides improved binding and dispersion properties to the multilayered semiconductor particle 300 when it is added to a polymer binder. In embodiments of the multilayered semiconductor particle 300 that include an outer shell 306 which contains ZnS material, the disulfide bonds of the sulfur component can provide crosslinking between the particle and the surrounding polymer binder. This can facilitate a more even dispersion of the particles in the polymer binder and reduce the number of emission hot spots and dark spots in a layer of the quantum dot material.

Method 100 may yet further include cooling the mixture of the fully-formed multilayered semiconductor particles 300 at operation 135. In embodiments, the cooling operation 135 may include more than one cooling stage characterized by different cooling ramp-down rates. The difference cooling stages may include a more rapid initial cooling of the particles to more precisely define the growth endpoint of the outer shell 306 and the size of the multilayered semiconductor particle 300. In further embodiments, the heated mixture of fully-formed particles may be cooled in a first cooling stage characterized by a first temperature ramp-down rate, followed by a second cooling stage characterized by a second cooling ramp-down rate. In embodiments, the first temperature ramp-down rate may be greater than or about 5° C./minute, greater than or about 6° C./minute, greater than or about 7° C./minute, greater than or about 8° C./minute, greater than or about 9° C./minute, greater than or about 10° C./minute, or more. In more embodiments, the second temperature ramp-down rate may be less than or about 4° C./minute, less than or about 3° C./minute, less than or about 2° C./minute, less than or about 1° C./minute, or less. In still more embodiments, a transition temperature from the first cooling stage to the second cooling stage may occur when the mixture of the fully-formed multilayered semiconductor particles 300 is characterized by a temperature of about 120° C., about 110° C., about 100° C., about 90° C., or about 80° C., among other transition temperatures. In yet further embodiments, the cooling operation 135 may reach completion when the mixture of the fully-formed multilayered semiconductor particles 300 is characterized by a temperature of less than or about 30° C.

Method 100 may still further include separating the multilayered semiconductor particles 300 from the residual components of the mixture in which they were formed at operation 140. In embodiments, the mixture of the fully-formed multilayered semiconductor particles 300 may include liquid organic compounds, including hydrocarbons, organic acids, organo-phosphine compounds, and organo-sulfur compounds, as well as residual reactants of the core, inner shell, and outer shell of the particles. In further embodiments, these liquid organic compounds may be separated from the multilayered semiconductor particles 300 by decanting the supernatant liquid from the concentrated mixture of the particles. In additional embodiments, the concentrated mixture of the particles may be mixed with one or more volatile organic solvents such as hexane and acetone, among other organic solvents. In more embodiments, the solvent mixture may be centrifuged to separate the mixture into sediment containing the multilayered semiconductor particles 300 and another supernatant containing the added organic solvents and an additional portion of the residual liquid organic compounds from the particle formation mixture. The supernatant may be separated from the sediment containing the multilayered semiconductor particles 300. In additional embodiments, the separated sediment may be contacted with more volatile organic solvents and centrifuged and separated for one or more additional washing cycles to produce an isolated batch of the multilayered semiconductor particles 300. In embodiments, the isolated batch of the multilayered semiconductor particles 300 may be contacted with a binder polymer composition and stored until use. In further embodiments, the binder polymer composition may include an acrylate compound. In still further embodiments, the acrylate compound may include 1,6-hexanediol diacrylate.

Referring now to FIG. 2, method 200 includes operations in additional methods of making multilayered semiconductor particles (i.e., the quantum dots) according to embodiments of the present technology. These embodiments include the rapid stirring of the core reactants during the formation of the QD core 302, as well as the rapid stirring of the inner and outer shell reactants in the particle-containing mixtures of the forming multilayered semiconductor particles 300. It has been discovered that the rapid stirring of the compounds facilitates their more even distribution throughout a mixture that is characterized by high viscosity and slow mass transport rates. The more even distribution of the reactants facilitates a more uniform formation of the multilayered semiconductor particles 300, which facilitates the particles having the desired emission characteristics.

Method 200 includes combining reactants for forming a quantum dot (QD) core at operation 205. In some embodiments, the QD core reactants may be combined gradually over a period of several minutes or more. In additional embodiments, the QD core reactants may be combined rapidly over a period of seconds, as described in method 100 above. In additional embodiments, the QD core reactants that are combined in operation 205 may include two or more semiconductor-containing reactants. In further embodiments, the QD core reactants may include at least one zinc-containing compound and at least one selenium-containing compound, among other QD core reactants. In more embodiments, the at least one zinc-containing compound may be anhydrous zinc acetate. In still more embodiments, the at least one selenium compound may be selenium complexed with triocetylphosphine. In embodiments, a first portion of the QD core reactants may react to form initial QD core particles, and operation 205 may include the addition of more QD core reactants to the mixture of initial QD core particles. In further embodiments, the additional reactants may include one or more tellurium-containing reactants, such as tellurium complexed with more triocetylphosphine. In still further embodiments, the tellurium may react with the initial ZnSe core particles to form a ZnSeTe core particles, such as QD core particle 302. In more embodiments, the ZnSeTe core particles may be characterized by a mole ratio of zinc to tellurium (Zn:Te) of less than or about 10:1, less than or about 5:1, less than or about 2.5:1, less than or about 1:1, less than or about 0.5:1, less than or about 0.25:1, or less.

Method 200 may additionally include rapidly stirring the reactant mixture at operation 210. In embodiments, the stirring may start with the combination of the first portion of the QD core reactants and continue during the formation of the initial QD core particles. In more embodiments, the stirring may occur during the combination of the additional reactants with the mixture of the initial QD core particles and may continue during the formation of the fully-formed QD core particles, such as QD core particle 302.

In further embodiments, the rapid stirring of the reactant and/or particle mixtures may be characterized by a stirring rate for a stirring mechanism in contact with the mixtures that is greater than or about 1000 rotations per minute (RPM), greater than or about 1100 RPM, greater than or about 1200 RPM, greater than or about 1300 RPM, greater than or about 1400 RPM, greater than or about 1500 RPM, greater than or about 1600 RPM, greater than or about 1700 RPM, greater than or about 1800 RPM, greater than or about 1900 RPM, greater than or about 2000 RPM, or more. In still further embodiments, the rapid stirring of the mixture may reduce the high viscosity of the mixture in an unstirred state. In embodiments, the rapid stirring of the mixture may reduce its viscosity by greater than or about 10%, greater than or about 25%, greater than or about 50%, greater than or about 75%, or more. The turbulence and reduction in the viscosity of the mixture due to the rapid stirring increase the mass transport rate of the reactants throughout the mixture. This can result in the formation of initial QD core particles of more uniform size, as well as more uniform sizes and compositions of the finally-formed QD core particles that include additional semiconductor materials such as tellurium.

Method 200 may also include heating the stirred reactant and/or particle mixture at operation 215. In embodiments, the stirred mixture may be heated to a temperature of greater than or about 250° C., greater than or about 260° C., greater than or about 270° C., greater than or about 280° C., greater than or about 290° C., greater than or about 300° C., or more, during the formation of the initial QD core and the fully-formed QD core.

Method 200 may yet also include cooling the heated and stirred mixture containing the fully-formed QD core particles 302 at operation 220. In some embodiments, the cooling mixture may remain rapidly stirred during the cooling operation. In additional embodiments, the stirring rate may be reduced during the cooling operation to facilitate the cooling of the mixture. In embodiments, the stirring rate may be reduced by greater than or about 5%, greater than or about 10%, greater than or about 15%, greater than or about 20%, greater than or about 25%, greater than or about 30%, greater than or about 40%, greater than or about 50%, or more, during the cooling operation. In further embodiments, the cooling operation may lower the temperature of the heated mixture to less than or about 290° C., less than or about 280° C., less than or about 270° C., less than or about 260° C., less than or about 250° C., or less. In additional embodiments, the decrease in temperature may be characterized by a temperature ramp-down rate of less than or about 10° C./minute, less than or about 7.5° C./minute, less than or about 5° C./minute, less than or about 2.5° C./minute, less than or about 1° C./minute, or less. In embodiments, the cooling operation reduces the temperature of the heated mixture of the QD core 302 particles in preparation for the addition of the inner shell reactants to the QD core particles. The reduced temperature, in conjunction with the stirring, permits the inner shell reactants to distribute more evenly through the QD core 302 particles before they react and form the inner shell layer 304 around the QD core 302.

Method 200 further includes stirring the particle mixture while introducing the inner shell reactants at operation 225. In embodiments, the stirring of the mixture of the inner shell reactants and QD core particles may be characterized by a stirring rate for a stirring mechanism in contact with the mixture that is greater than or about 1000 rotations per minute (RPM), greater than or about 1100 RPM, greater than or about 1200 RPM, greater than or about 1300 RPM, greater than or about 1400 RPM, greater than or about 1500 RPM, greater than or about 1600 RPM, greater than or about 1700 RPM, greater than or about 1800 RPM, greater than or about 1900 RPM, greater than or about 2000 RPM, or more. In still further embodiments, the stirred mixture may be heated to a temperature of greater than or about 250° C., greater than or about 260° C., greater than or about 270° C., greater than or about 280° C., greater than or about 290° C., greater than or about 300° C., or more, during the formation of the inner shell 304 on the QD core 302.

In embodiments, the inner shell reactants may include a zinc-containing reactant and a selenium-containing reactant, among other reactants. In additional embodiments, the zinc-containing reactant may include anhydrous zinc acetate, and the selenium-containing reactant may include selenium combined with a complexing agent such as triocetylphosphine. In further embodiments, the inner shell reactants may include additional compounds such as unsaturated or saturated alkyl hydrocarbons and organic acids. In still further embodiments, the unsaturated or saturated alkyl hydrocarbons may include 1-octadecene, and the organic acids may include oleic acid. In more embodiments, the inner shell 304 formed from the inner shell reactants may include a zinc-selenium (ZnSe) material. In yet more embodiments, the inner shell 304 may be characterized by a mole ratio of zinc-to-selenium that is less than or about 4:1, less than or about 2:1, less than or about 1:1, less than or about 0.5:1, less than or about 0.25: 1, or less.

Method 200 may still also include stirring the particle mixture while introducing the outer shell reactants at operation 230. In embodiments, the stirring of the mixture of the outer shell reactants and further forming QD particles may be characterized by a stirring rate for a stirring mechanism in contact with the mixture that is greater than or about 1000 rotations per minute (RPM), greater than or about 1100 RPM, greater than or about 1200 RPM, greater than or about 1300 RPM, greater than or about 1400 RPM, greater than or about 1500 RPM, greater than or about 1600 RPM, greater than or about 1700 RPM, greater than or about 1800 RPM, greater than or about 1900 RPM, greater than or about 2000 RPM, or more. In still further embodiments, the stirred mixture may be heated to a temperature of greater than or about 250° C., greater than or about 260° C., greater than or about 270° C., greater than or about 280° C., greater than or about 290° C., greater than or about 300° C., or more, during the formation of the outer shell 306 on the inner shell 304 of the multilayered semiconductor particles 300.

In further embodiments, the outer shell reactants may include a zinc-containing reactant and a sulfur-containing reactant, among other reactants. In additional embodiments, the zinc-containing reactant may include anhydrous zinc acetate, and the sulfur-containing reactant may include sulfur combined with a complexing agent such as triocetylphosphine. In further embodiments, the outer shell reactants may include additional compounds such as unsaturated or saturated alkyl hydrocarbons and organic acids. In still further embodiments, the unsaturated or saturated alkyl hydrocarbons may include 1-octadecene, and the organic acids may include oleic acid. In more embodiments, the outer shell 306 formed from the outer shell reactants may include a zinc sulfide (ZnS) material. In still more embodiments, the outer shell 306 may be characterized by a mole ratio of zinc-to-sulfur that is less than or about 5:1, less than or about 2.5:1, less than or about 1:1, less than or about 0.5:1, less than or about 0.4:1, less than or about 0.3:1, less than or about 0.2:1, or less.

Method 200 may yet further include cooling the mixture of the fully-formed multilayered semiconductor particles 300 at operation 235. In embodiments, the cooling operation 235 may include a single cooling stage or two or more cooling stages. In additional embodiments, the mixture may be stirred while the cooling operation is conducted. In embodiments with two or more cooling stages, the cooling stages may be characterized by different cooling ramp-down rates as described above in method 100.

Method 200 may still further include separating the multilayered semiconductor particles 300 from the residual components of the mixture in which they were formed at operation 240. In embodiments, the mixture of the fully-formed multilayered semiconductor particles 300 may include liquid organic compounds, including hydrocarbons, organic acids, organo-phosphine compounds, and organo-sulfur compounds, as well as residual reactants of the core, inner shell, and outer shell of the particles. In further embodiments, these liquid organic compounds may be separated from the multilayered semiconductor particles 300 by decanting the supernatant liquid from the concentrated mixture of the particles. In additional embodiments, the concentrated mixture of the particles may be mixed with one or more volatile organic solvents such as hexane and acetone, among other organic solvents. In more embodiments, the solvent mixture may be centrifuged to separate the mixture into sediment containing the multilayered semiconductor particles 300 and another supernatant containing the added organic solvents and an additional portion of the residual liquid organic compounds from the particle formation mixture. The supernatant may be separated from the sediment containing the multilayered semiconductor particles 300. In additional embodiments, the separated sediment may be contacted with more volatile organic solvents and centrifuged and separated for one or more additional washing cycles to produce an isolated batch of the multilayered semiconductor particles 300. In embodiments, the isolated batch of the multilayered semiconductor particles 300 may be contacted with a binder polymer composition and stored until use. In further embodiments, the binder polymer composition may include an acrylate compound. In still further embodiments, the acrylate compound may include 1,6-hexanediol diacrylate.

In both method 100 and 200 the various reactant and particle mixtures may be characterized by low moisture. In embodiments, the mixtures may be characterized by moisture levels of less than or about 1 wt.%, less than or about 0.75 wt.%, less than or about 0.5 wt.%, less than or about 0.25 wt.%, less than or about 0.1 wt.%, less than or about 0.05 wt.%, or less. In further embodiments, the mixtures may be characterized as free of hydrated compounds that have one or more water molecules incorporated into the compound. The low moisture levels in the reactants and mixtures reduce the number of side products produced instead of the multilayered semiconductor particles 300. In embodiments, the low moisture levels provide mixtures with lower amounts of semiconductor hydroxide compounds such as zinc hydroxide, selenium hydroxide, and tellurium hydroxide, among other semiconductor hydroxides, that can precipitate out of the mixture to prevent the semiconductor material from being incorporated into the multilayered semiconductor particles 300.

Also, in methods 100 and 200, the various reactant and particle mixtures in heated states (e.g., greater than or about 80° C.) are held in anoxic atmospheres to reduce or prevent the oxidation of compounds in the mixtures. In embodiments, the reactant and particle mixtures may be heated in an anoxic atmosphere to reduce or prevent the oxidation of zinc-containing compounds, selenium-containing compounds, tellurium-containing compounds, and trialkyl-phosphine compounds, among other compounds in the mixtures. The anoxic atmospheres also reduce the fire hazard risk during the formation of the quantum dot particles. The reactants and mixtures include many pyrophoric compounds that may be heated to temperatures of 300° C. or more. In an oxygen-containing environment such as ambient air, there is a high probability these reactants and mixtures will catch fire at such temperatures. In embodiments, the reactant and particle mixtures in heated states are held in anoxic atmospheres that include dry nitrogen (N₂) and/or argon (Ar), among other inert gases. In embodiments, these anoxic atmospheres may be characterized by levels of molecular oxygen (O₂) of less than or about 1 wt.%, less than or about 0.75 wt.%, less than or about 0.5 wt.%, less than or about 0.25 wt.%, less than or about 0.1 wt.%, less than or about 0.05 wt.%, or less.

Methods 100 and 200 can make multilayered semiconductor particles 300 that are characterized by an increased sharpness and fewer secondary emission peaks than quantum dot particles made by conventional methods. In embodiments, the light emitted by the multilayer semiconductor particles 300 may be characterized by a peak wavelength emission of less than or about 500 nm, less than or about 490 nm, less than or about 480 nm, less than or about 470 nm, less than or about 460 nm, less than or about 450 nm, less than or about 440 nm, less than or about 430 nm, less than or about 420 nm, less than or about 410 nm, less than or about 400 nm, less than or about 390 nm, less than or about 380 nm, or less. In additional embodiments, the light emitted by the multilayer semiconductor particles 300 may be characterized by a peak wavelength emission of less than or about 455 nm. In further embodiments, the light emitted by the multilayer semiconductor particles 300 may have a narrowband (i.e., sharp) color profile that is characterized by a full-width-half-maximum (FWHM) primary wavelength emission peak that is less than or about 40 nm, less than or about 35 nm, less than or about 30 nm, less than or about 25 nm, less than or about 20 nm, less than or about 15 nm, less than or about 10 nm, less than or about 5 nm, less than or about 2.5 nm, less than or about 1 nm, or less.

In embodiments, the sharpness of the primary wavelength emission peak is due at least in part to fewer and less intense secondary wavelength emission peaks from the excited multilayered semiconductor particles 300. In additional embodiments, the ratio of light emission intensity between the primary wavelength emission peak and the next most intense secondary wavelength emission peak may be greater than or about 5:1, greater than or about 10:1, greater than or about 15:1, greater than or about 20:1, greater than or about 30:1, greater than or about 40:1, greater than or about 50:1, or more. The reduced intensity of the secondary wavelength emission peaks is due at least in part to the increased uniformity of the composition, size, and morphology of the multilayered semiconductor particles 300 made according to embodiments of the present technology.

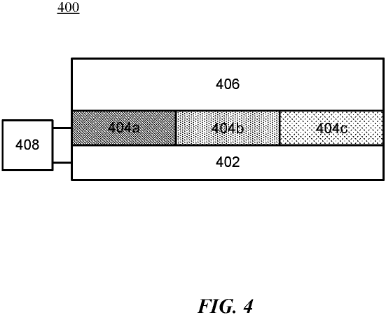

Referring now to FIG. 4, a simplified cross-section of a display device 400 is shown that includes multilayered semiconductor particles (i.e., quantum dots) according to embodiments of the present technology. Display device 400 includes a light source 402 that excites three areas of quantum dots 404a-c that are operable to emit light of different colors upon being excited with the light source 402. In embodiments, first quantum dot area 404a may be operable to emit blue light, second quantum dot area 404b may be operable to emit green light, and third quantum dot area 404c may be operable to emit red light. In further embodiments, the multilayered semiconductor particles according to embodiments of the present technology may be incorporated into the first quantum dot area 404a and may be operable to emit a sharp blue with a peak narrowband emission wavelength of less than or about 455 nm.

In embodiments, the display device 400 may be operable to excite the quantum dot areas 404a-c at varying intensities with the source light 402. In further embodiments, the source light 402 may include one or more light-emitting-diodes operable to emit light at shorter, more energetic wavelengths than the light emitted by the quantum dot areas 404a-c. In additional embodiments, the source light may be operable to emit an ultraviolet excitation light characterized by a peak emission wavelength of less than or about 350 nm. In more embodiments, the source light may be operable to emit white light characterized by a broad emission of light across the visible spectrum (e.g., 380 nm to 750 nm).

In additional embodiments, the display device 400 may be operable to display an image by activating the source light 402 to excite the quantum dot areas 404a-c, which emit colored light through a translucent front panel 406 that projects the image. In more embodiments, a controller 408 is coupled through electronic circuitry (not shown) to the light source 402 and the quantum dot areas 404a-c. The controller 408 may be operable to receive input signals for the display of an image and transmit output signals that activate and deactivate portions of the light source 402 and the quantum dot areas 404a-c.

Embodiments of the present technology permit the making of multilayered semiconductor particles (i.e., quantum dots) that are characterized by improved sharpness of the color emitted by the quantum dots. The embodiments include improvements in the fabrication methods such as the rapid combination of the core and shell layer reactants and the rapid stirring of the reactants and forming quantum dot particles. The embodiments also include fabricating the quantum dots in low moisture mixtures that are held in anoxic atmospheres that may include dry nitrogen, argon, or mixtures of both. The improved methods can make quantum dots with narrowband emission features, such as a primary emission wavelength peak characterized by a FWHM of less than or about 40 nm.

In the preceding description, for the purposes of explanation, numerous details have been set forth in order to provide an understanding of various embodiments of the present technology. It will be apparent to one skilled in the art, however, that certain embodiments may be practiced without some of these details, or with additional details. For example, other substrates that may benefit from the wetting techniques described may also be used with the present technology.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included. Where multiple values are provided in a list, any range encompassing or based on any of those values is similarly specifically disclosed.

As used herein and in the appended claims, the singular forms “a”, “an”, and “the” include plural references unless the context clearly dictates otherwise. Thus, for example, reference to “a compound” includes a plurality of such compounds, and reference to “the period of time” includes reference to one or more periods of time and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A method of making a multilayered semiconductor particle, the method comprising:
combining a first zinc-containing compound and a selenium-containing compound to form a ZnSe mixture, wherein the zinc-containing compound and the selenium-containing compound are combined in less than or about 5 seconds;
adding a tellurium-containing compound to the ZnSe mixture to form at least one ZnSeTe particle in a ZnSeTe mixture;
forming a first shell layer on the ZnSeTe particle; and
forming a second shell layer on the first shell layer formed on the ZnSeTe particle to make the multilayered semiconductor particle.

2. The method of claim 1, wherein the tellurium-containing compound is added to the ZnSe mixture in less than or about 5 seconds.

3. The method of claim 1, wherein the method further comprises increasing a temperature of the ZnSeTe mixture at a rate greater than or about 10° C./minute.

4. The method of claim 1, wherein the method further comprises stirring the ZnSeTe mixture with a stirring mechanism rotating at greater than or about 1500 RPM.

5. The method of claim 1, wherein the tellurium-containing compound is added to the ZnSe mixture in an atmosphere comprising less than or about 1 mol.% oxygen.

6. The method of claim 1, wherein the ZnSeTe mixture comprises less than or about 1 wt.% water.

7. The method of claim 1, wherein the first shell layer comprises zinc selenide.

8. The method of claim 1, wherein the second shell layer comprises zinc sulfide.

9. A method of making a multilayered semiconductor particle, the method comprising:
combining a first zinc-containing compound and a selenium-containing compound to form a ZnSe mixture;
adding a tellurium-containing compound to the ZnSe mixture to form at least one ZnSeTe particle in a particle forming mixture, wherein the particle forming mixture is stirred with a stirring mechanism rotating at greater than or about 1500 RPM during the formation of the at least one ZnSeTe particle;
forming a ZnSe-containing shell layer on the ZnSeTe particle; and
forming a ZnS-containing shell layer on the ZnSe-containing shell layer formed on the ZnSeTe particle to make the multilayered semiconductor particle.

10. The method of claim 9, wherein the particle forming mixture is stirred with the stirring mechanism rotating at greater than or about 1500 RPM during the formation of the ZnSe-containing shell layer and the ZnS-containing shell layer.

11. The method of claim 9, wherein the zinc-containing compound and the selenium-containing compound are combined in less than or about 5 seconds.

12. The method of claim 9, wherein the tellurium-containing compound is added to the ZnSe mixture in less than or about 5 seconds.

13. The method of claim 9, wherein the particle forming mixture is characterized by a temperature of greater than or about 300° C. during the formation of the at least one ZnSeTe particle.

14. The method of claim 9, wherein the particle forming mixture comprises an alkyl phosphine compound.

15. A multilayered semiconductor particle comprising:
a core comprising ZnSeTe;
an inner shell layer in contact with the core, wherein the inner shell layer comprises ZnSe; and
an outer shell layer in contact with the inner shell layer, wherein the outer shell layer comprises ZnS,
wherein the multilayered semiconductor particle has a light emission spectrum characterized by a primary peak with a full-width-half-maximum wavelength range of less than or about 40 nm.

16. The multilayered semiconductor particle of claim 15, wherein the primary peak of the light emission spectrum is less than or about 455 nm.

17. The multilayered semiconductor particle of claim 15, wherein an emission intensity of the primary peak of the light emission spectrum exceeds an emission intensity of every other emission peak in the light emission spectrum by a ratio of greater than or about 10:1.

18. The multilayered semiconductor particle of claim 15, wherein the multilayered semiconductor particle is characterized by an average particle size of less than or about 10 nm.

19. The multilayered semiconductor particle of claim 15, wherein the core is sulfur free.

20. The multilayered semiconductor particle of claim 15, wherein the multilayered semiconductor particle is incorporated into a microLED device.
